(19) United States
(12) Patent Application Publication
(10) Pub. No.: US 2009/0008139 A1
(43) Pub. Date: Jan. 8, 2009

(54) MULTILAYER PWB AND A METHOD FOR PRODUCING THE MULTILAYER PWB

(75) Inventors: Patrik Lundell, Svedala (SE); Stefan Eskilsson, Lomma (SE); Thomas Ahlberg, Lund (SE)

Correspondence Address: WARREN A. SKLAR (SOER);RENNER, OTTO, BOISSELLE & SKLAR, LLP, 1621 EUCLID AVENUE, 19TH FLOOR, CLEVELAND, OH, 44115, US

(73) Assignee: SONY ERICSSON MOBILE COMMUNICATIONS AB, Lund (SE)

(21) Appl. No.: 11/772,904

(22) Filed: Jul. 3, 2007

(51) Int. Cl. H05K 1/18; H05K 1/00; H05K 3/00

(52) U.S. Cl. 174/260; 174/250; 29/846

(57) ABSTRACT

A multilayered printed wiring board, a multilayer PWB, and a method for manufacturing the same. The multilayer PWB comprises a first main surface and an opposing second main surface, where the multilayer PWB has a height being defined by the distance from the first main surface to the opposing second main surface. The two surfaces and the height together define the thickness of the multilayer PWB. The multilayer PWB comprises a reference ground plane, a microstrip conductor separated from the reference ground plane by a first dielectric layer and a stripline conductor connected with the microstrip conductor and being separated from the reference ground plane by a second dielectric layer. The reference ground plane is formed by two or more different partial reference ground planes positioned at different layers of the multilayer PWB. Furthermore, the reference ground plane is moveable from the first partial reference ground plane to the second partial reference ground plane when a signal current transits from the microstrip conductor to the stripline conductor, and vice versa.

### TECHNICAL FIELD

The present invention relates to a printed wiring board (PWB) and a method for producing the same. More particularly, the invention relates to a multilayer PWB, with a first main surface and an opposing second main surface, wherein the multilayer PWB has a height which is defined by the distance from the first main surface to the opposing second main surface. The two surfaces and the height together define the volume or thickness of the multilayer PWB. The multilayer PWB comprises a reference ground plane, a microstrip conductor separated from the reference ground plane by a first dielectric layer, as well as a stripline conductor connected with the microstrip conductor and further being separated from the reference ground plane by a second dielectric layer.

### BACKGROUND

The first commercially attractive mobile telephones or terminals were introduced in the market at the end of the 1980's. Since then, the mobile communications industry has had an enormous development both regarding quality of service and transmission capabilities, as well as the technology for producing advanced communications terminals. A lot of effort has been made in making smaller and thinner terminals, with much help from the miniaturization of electronic components. However, there is still a strive towards even smaller and thinner terminals. Therefore, all possible aspects are continuously considered by mobile phone manufacturers and others in order to be able to produce as small and/or thin mobile terminals as possible.

A possible way of reducing or limiting the size of mobile terminals is to focus on the size of the PWB's. A common approach of building PWB's is known as the multilayer technique, which means that the PWB consists of a number of layers, where layers comprising a pattern made of an electrically conductive material are arranged on layers of dielectric material. Certain of the layers of electrically conductive material may also be intended for use as a ground plane, in which case the layer is normally designed as a rectangular plate in the prior art. For the functioning of the PWB, it may be necessary to interconnect certain of the various layers at points where it is desirable to have electrical contact. A known way for accomplishing this is to utilize what is commonly known as via-holes. Via-holes are holes which are drilled or made in another manner vertically in the PWB between the points which are to be connected.

FIG. 1 illustrates a simplified cross-sectional view of a state of the art PWB 100 for mobile terminals, e.g., mobile phones. The PWB 100 is intended for use in radio frequency (RF) ranges, in which mobile phones operate. The PWB 100 comprises two conductive layers which are to be connected, in the example shown a microstrip conductor 110 and a stripline conductor 120. The microstrip conductor 110 and the stripline conductor 120, respectively, are arranged one on each side of a reference ground plane 130. Also, in some of the layers of the PWB 100, other conductors 140 may be present. Possible application areas of the PWB 100 in FIG. 1 include what is commonly known as integrated electronics. The stripline conductor may form part of what is known as a distribution network in order to interconnect various layers of the PWB. The microstrip conductor may be utilized for connection of electronic components.

The microstrip conductor in the PWB 100 may comprise the conductor 110 itself, the reference ground 130 and a layer 150 of dielectric material. The microstrip conductor 110 may be made of a thin conductive layer. The electrical conductor 110 is separated from the reference ground plane 130 by the dielectric layer 150. In general, microstrip conductors are used in PWB designs where high frequency signals need to be routed from one part of the PWB assembly to another with high efficiency and minimal signal loss. They are of a class of electrical conductors called transmission lines, having specific electrical properties that are determined by conductor width and resistivity, and spacing from the ground plane 130, as well as dielectric properties of the insulating layer.

The stripline conductor in the PWB 100 may comprise the conductor 120 itself, layers 160, 161 of dielectric material one on each side of the conductive layer 120, and two ground planes 130, 170 which are in turn located one on each side of the layers 160, 161 of dielectric material. The stripline conductor can thus be said to utilize a flat strip of conductive layer 120 which is sandwiched between two parallel ground planes 130, 170. The width of the stripline conductor 120, the thickness of the layers 160, 161 and the relative permittivity of the layers 160, 161 may determine the characteristic impedance of the strip 120, which is a transmission line. The stripline conductor 120 need not be equally spaced between the ground planes 130, 170. Generally speaking, the dielectric material 160 may be different from the dielectric material 161. Accordingly, the dielectric material 160, 161 may be different above and below the stripline conductor 120. The stripline transmission line in the form of the stripline conductor 120 is similar to the microstrip conductor 110, except that the microstrip conductor 110 is not sandwiched; it is on a surface layer, above the ground plane 130.

In the prior art configuration of the PWB shown in FIG. 1, the conductors 110, 120 are normally matched to be 50 Ohm of characteristic impedance. It is common that the PWB uses a combination of microstrip conductors 110 and stripline conductors 120, as is illustrated in FIG. 1. The microstrip conductor 110 is connected to the stripline conductor 120 through via-holes 170. When a signal current is transmitted from microstrip conductors to stripline conductors or vice versa, the same ground plane, denoted 130 in FIG. 1, is used as one single and complete reference ground plane for both the microstrip conductors and the stripline conductors. That is, the reference ground plane denoted 130 in FIG. 1 is common to both microstrip conductors and stripline conductors. In other words, the pre-defined reference ground plane 130 is configured to act as a reference ground plane for both microstrip conductors and stripline conductors. In the known prior art, the reference ground plane 130 in FIG. 1 is also positioned at one pre-defined layer of the multilayer PWB. The inventors have realized that a disadvantage with the above-mentioned state of the art PWB configuration is that the PWB becomes unnecessarily thick. That is, the thickness of the PWB 100 as defined by the height h in FIG. 1 is unnecessarily thick.

### SUMMARY OF THE INVENTION

With the above and following description in mind, then, an aspect of some embodiments of the present invention is to provide an improved PWB, which seeks to mitigate, alleviate or eliminate one or more of the above-identified deficiencies in the art and disadvantages singly or in any combination.

An aspect of the present invention relates to multilayer printed wiring board, a multilayer PWB, with a first main surface and an opposing second main surface, the PWB having a height being defined by the distance from the first main surface to the opposing second main surface, said two surfaces and height together defining the thickness of the PWB, wherein the PWB comprises a reference ground plane, a microstrip conductor separated from the reference ground plane by a first dielectric layer, and a stripline conductor connected with the microstrip conductor and being separated from the reference ground plane by a second dielectric layer; wherein

the reference ground plane is formed by at least two different partial reference ground planes positioned at different layers of the multilayer PWB, the reference ground plane being moveable from a first partial reference ground plane to a second partial reference ground plane when a signal current transits from the microstrip conductor to the stripline conductor, and vice versa.

In one embodiment, the at least two partial reference ground planes at the different layers of the multilayer PWB are interconnected with each other by means of at least one via-hole.

In one embodiment, the at least two partial reference ground planes are interconnected through said via-hole such that a return current in the reference ground plane is moveable between the at least two partial reference ground planes for following signal currents through the multilayer PWB when signal currents transit from the microstrip conductor to the stripline conductor, and vice versa.

Another aspect of the present invention relates to an electronic device, comprising the above-mentioned multilayer PWB.

The electronic device may be a device from the group comprising: a portable radio communication equipment, a mobile radio terminal, a mobile telephone, a cellular telephone, a pager, a communicator, an electronic organizer, a smart phone, a camera device, a media player, and etcetera.

Still another aspect of the present invention relates to method of manufacturing a multilayer printed wiring board, a multilayer PWB, said PWB having a first main surface and an opposing second main surface, the PWB having a height being defined by the distance from the first main surface to the opposing second main surface, said two surfaces and height together defining the thickness of the PWB, the method comprising:

arranging a reference ground plane,

arranging a microstrip conductor such that the microstrip conductor is separated from the reference ground plane by a first dielectric layer,

arranging a stripline conductor such that the stripline conductor is separated from the reference ground plane by a second dielectric layer; and

connecting the microstrip conductor with the stripline conductor; the method further comprising:

arranging at least two different partial reference ground planes at different layers of the multilayer PWB for thereby forming the reference ground plane in such way that the reference ground plane becomes moveable from a first partial reference ground plane to a second partial reference ground plane when a signal current transits from the microstrip conductor to the stripline conductor, and vice versa.

In one embodiment, the method further comprises:

interconnecting the at least two partial reference ground planes at the different layers of the multilayer PWB by means of at least one via-hole.

In one embodiment, the method further comprises:

interconnecting the at least two partial reference ground planes at the different layers of the multilayer PWB by means of the at least one via-hole such that a return current in the reference ground plane becomes moveable between the at least two partial reference ground planes for thereby following signal currents through the multilayer PWB when signal currents transit from the microstrip conductor to the stripline conductor, and vice versa.

Some embodiments of the present invention provide for a multilayer PWB with a reduced thickness as compared to prior art multilayer PWB's. It is an advantage with some embodiments of the invention that they allow for a PWB that can be made thinner than prior art PWB's, since this may in turn also lead to reduced manufacturing costs for producing the multilayer PWB. It is also an advantage with some of the embodiments of this invention that they may allow for the further miniaturization of mobile terminals, e.g. mobile phones, including such multilayer PWB's.

### BRIEF DESCRIPTION OF THE DRAWINGS

Further objects, features and advantages of the present invention will appear from the following detailed description of the invention, wherein embodiments of the invention will be described in more detail with reference to the accompanying drawings, in which:

FIG. 1 is a cross-sectional view from the side of a state of the art multilayer PWB;

FIG. 2A is a plane view from above of a multilayer PWB according to an embodiment of the present invention;

FIG. 2B illustrates the PWB of FIG. 2A in cross section along the line IV-IV seen from the direction of the arrow d;

FIG. 3A is a plane view from above of a multilayer PWB according to another embodiment of the present invention;

FIG. 3B illustrates the PWB of FIG. 3A in cross section along the line VI-VI seen from the direction of the arrow d;

FIG. 4 is a flow chart illustrating a method of manufacturing a multilayer PWB in accordance with an embodiment of the invention; and

FIG. 5 is a flow chart illustrating some of the steps of the method illustrated in FIG. 4.

### DETAILED DESCRIPTION

Embodiments of the present invention relate to the field of PWB's and, more particularly, to the field of multilayer PWB's for radio frequency applications. A preferred embodiment relates to a multilayer PWB suitable for implementation in a portable communication device, such as a mobile phone. However, it should be appreciated that the invention is as such equally applicable to electronic devices which do not include any radio communication capabilities. However, for the sake of clarity and simplicity, most embodiments outlined in this specification are related to mobile phones.

Embodiments of the present invention will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference signs refer to like elements throughout.

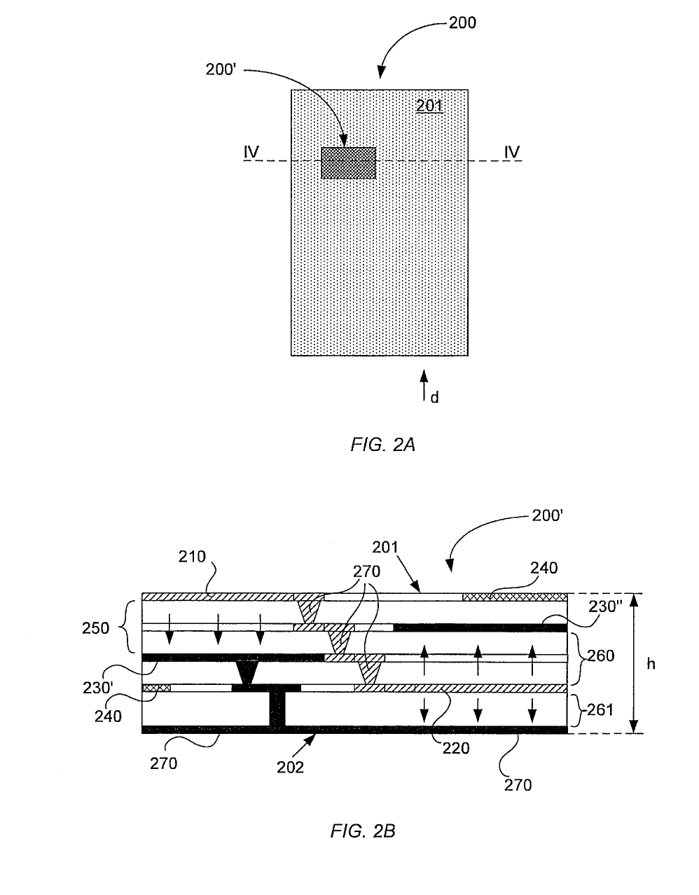

FIG. 2A illustrates a plan view from above of an embodiment of a printed wiring board, a PWB, 200 in accordance with the invention. As can be seen, the PWB has a first main surface 201, which is essentially rectangular in shape, although this shape can be varied within the scope of the invention.

FIG. 2B is a view from the side of the PWB 200, along the line IV-IV as seen from the direction indicated by arrow d in FIG. 2A. As can be seen in this figure, the PWB 200 further comprises a second main surface 202. The PWB is a multilayer PWB comprising a number of layers. The PWB 200 may comprise layers of a first supporting laminate material, suitably but not necessarily FR4, interwoven with layers of a first conducting material such as for example copper or aluminum. In addition to these material layers, the PWB may also comprise layers of a so-called “prepreg”. The material referred to consistently in this specification as “prepreg” is used as a bonding material to fix rigid laminate and to fill space or cavities between them, for instance, layers inside PWB's such that air pockets are essentially eliminated. Prepreg has a semi-cured chemistry and can therefore be formed under certain pre-defined combinations of heat, pressure and vacuum. Once the prepreg has cured completely, it is fixed and will stay in that shape. As an alternative to prepreg, so-called bonding films may be used to fix different material layers to each other and to fill cavities between material layers inside the multilayer PWB. Bonding films may, e.g., be formed by heat, pressure and vacuum. The above-mentioned materials, i.e. laminate materials, conducting materials, and prepreg, have respective dielectric constants ε and loss factors, the latter also being commonly known as the dissipation factor of the material.

In FIG. 2B, a simplified cross-sectional view of a sub-area 200′ (see FIG. 2A) of the multilayer PWB 200 is schematically illustrated. The PWB 200 can suitably, but not necessarily, be implemented in a mobile terminal, e.g., a mobile phone. As such, the PWB 200 is intended for use in radio RF ranges, in which said mobile phone operates. Possible application areas of the PWB 200 in FIGS. 2A and 2B include what is commonly known as integrated electronics. A stripline conductor may form part of what is known as a distribution network in order to interconnect various layers of the PWB. A microstrip conductor may be utilized for connection of electronic components.

The PWB 200 illustrated in FIG. 2 comprises two conductors which are to be connected through via-holes 270. In the example shown, the two conductors are a microstrip conductor 210 and a stripline conductor 220, respectively. The microstrip conductor in the PWB 200 may comprise the conductor 210 itself, a partial reference ground plane 230′ and a layer 250 of dielectric material. The microstrip conductor 210 may be made of a thin conductive layer. The electrical conductor 210 is separated from the partial reference ground plane 230′ by the dielectric layer 260. The stripline conductor in the PWB 200 may comprise the conductor 220 itself, two layers 260, 261 of dielectric material one on each side of the conductive layer 220, and two ground planes 230″, 270 which are in turn located one on each side of the layers 260, 261 of dielectric material. The stripline conductor may thus utilize a flat strip of conductive layer 220 which is sandwiched between two parallel ground planes 230″, 270. The width of the stripline conductor 220, the thickness of the layers 260, 261 and the relative permittivity of the layers 260, 261 may determine the characteristic impedance of the strip 220, which is a transmission line. The stripline conductor 220 need not necessarily be equally spaced between the ground planes 230″, 270. Generally speaking, the dielectric material 260 may be different from the dielectric material 261. Accordingly, the dielectric material 260, 261 may be different above and below the stripline conductor 220. The stripline transmission line in the form of the stripline conductor 220 is similar to the microstrip conductor 210, except that the microstrip conductor 210 is not sandwiched; in the example shown it is on a surface layer, above the partial ground plane 230′.

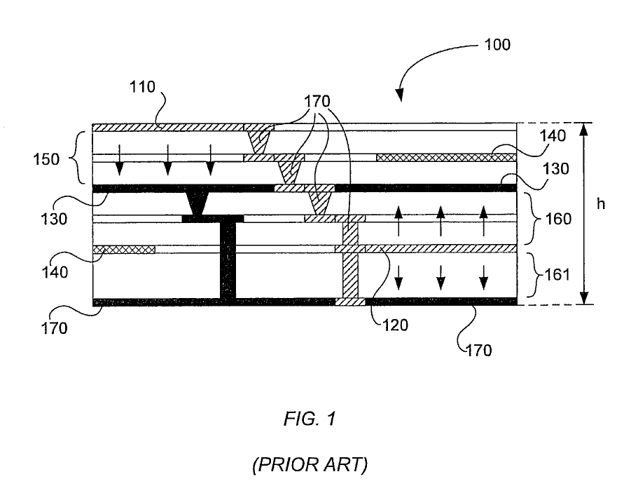

The presented PWB configuration of the PWB 200 illustrated in FIG. 2 is different from the prior art solution described in conjunction with FIG. 1, inter alia, in that it assumes the use of two or more different partial or locally arranged reference ground planes 230′, 230″ positioned at different layers of the multilayer PWB 200. The reference ground plane 230 is moveable from a first partial or locally arranged reference ground plane 230′ to a second partial or locally arranged reference ground plane 230″ when a signal current transits in the direction from the microstrip conductor 210 to the stripline conductor 220, and vice versa. By moving the reference ground plane 230 between the different partial reference ground planes 230′, 230″ positioned at the different layers of the PWB 200 when the signal current goes from the microstrip conductor 210 to the stripline conductor 220 and vice versa the total number of layers used in multilayer PWB 200 can be reduced. Hence, as compared with the prior art configuration of the PWB 100, the total thickness h of the PWB 200 can be reduced. The inventive idea is to let return currents in the partial ground planes 230′, 230″ follow the signal currents through the PWB 200. The two or more partial reference ground planes 230′, 230″ may be interconnected by means of via-holes (not shown) around transition points which are arranged in proximity to a location where signal currents are configured to transit between the different layers of the PWB 200. The reference ground plane 230 can thus be said to be configured to jump or move between layers of the PWB 200 by utilizing different partial or locally arranged reference ground planes 230′, 230″ to maintain correct impedance for the conductors 210, 220. This way, the two or more partial reference ground planes 230′ 230″, which are arranged in relation to each other in such way that the partial ground planes are mutually arranged at different distances from one of the main surfaces 201, 202, together form a single virtual reference plane 230. In view of the above discussion, the inventive idea can be said to provide a PWB 200 with a jumping or moving reference ground plane 230.

It has turned out that it may be advantageous to provide the PWB 200 with partial or locally arranged ground planes 230′, 230″ which have a width which is about 10 times (or more) the width of the corresponding microstrip conductor 210 or stripline conductor 220, on both sides. As a mere example, if the microstrip conductor 210 is 0.1 mm wide, the partial ground plane 230′ should be at least 2 mm wide, i.e. approximately 10 times wider on each side.

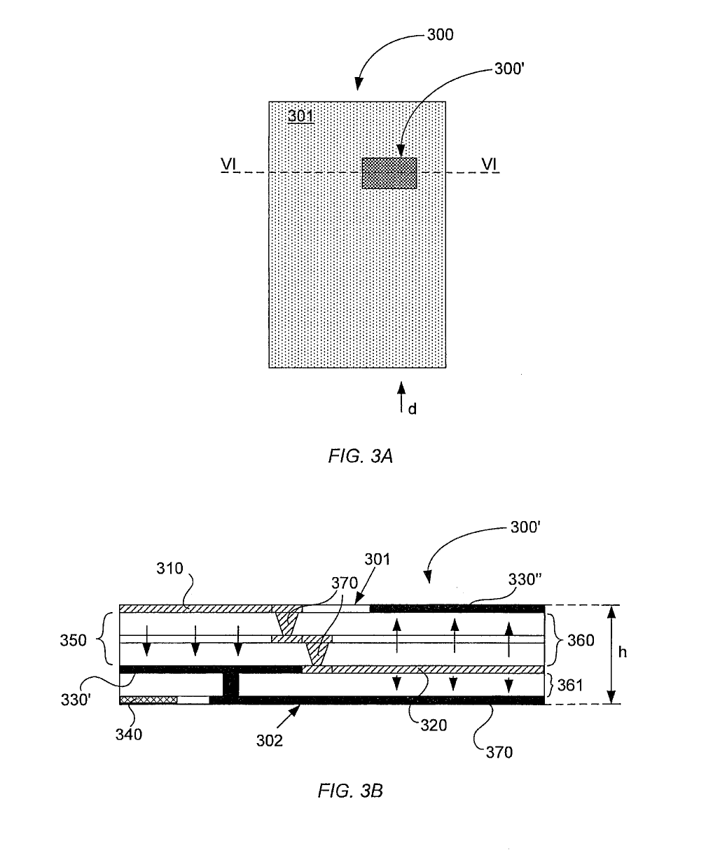

FIG. 3A illustrates a plan view from above of another embodiment of a printed wiring board, a PWB, 300 in accordance with the invention. The PWB 300 has a first main surface 301, which is essentially rectangular in shape, although this shape can be varied within the scope of the invention. FIG. 3B is a view from the side of the PWB 300, along the line VI-VI as seen from the direction indicated by arrow d in FIG. 3A. As can be seen in this figure, the PWB 300 further comprises a second main surface 302. The PWB is multilayer PWB comprising a number of layers and is similar to the embodiment described in conjunction with FIGS. 2A and 2B. In FIG. 3B, a simplified cross-sectional view of a sub-area 300′ (see FIG. 3A) of the multilayer PWB 300 is schematically illustrated. The PWB 300 can suitably, but not necessarily, be implemented in a mobile terminal, e.g., a mobile phone. As such, the PWB 300 is intended for use in RF ranges, in which said mobile phone operates. Like the embodiment described earlier in conjunction with FIGS. 2A and 2B, the PWB 300 comprises two conductors which are to be connected through via-holes 370. The conductors are a microstrip conductor 310 and a stripline conductor 320, respectively. The microstrip conductor in the PWB 300 may comprise the conductor 310 itself, a partial reference ground plane 330′ and a layer 350 of dielectric material. The microstrip conductor 310 may be made of a thin conductive layer. The electrical conductor 310 is separated from the partial reference ground plane 330′ by the dielectric layer 360. The stripline conductor in the PWB 300 may comprise the conductor 320 itself, layers 360, 361 of dielectric material one on each side of the conductive layer 320, and two ground planes 330″, 370 which are in turn located one on each side of the layers 360, 361 of dielectric material. The stripline conductor can thus be said to utilize a flat strip of conductive layer 320 which is sandwiched between two parallel ground planes 330″, 370.

Like the embodiment described in conjunction with FIGS. 2A and 2B, the presented PWB configuration of the PWB 300 illustrated in FIG. 3 is different from prior art solutions, inter alia, in that it assumes the use of two or more different partial or locally arranged reference ground planes 330′, 330″ positioned at different layers of the multilayer PWB 300. The reference ground plane 330 is moveable from a first partial or locally arranged reference ground plane 330′ to a second partial or locally arranged reference ground plane 330″ when a signal current transits in the direction from the microstrip conductor 310 to the stripline conductor 320, and vice versa. Thus, like in the previously described embodiment, the reference ground plane 330 can be said to move or follow a signal current which transits from the microstrip conductor 310 to the stripline conductor 320, or vice versa. By moving the reference ground plane 330 when the signal current goes from the microstrip conductor 310 to the stripline conductor 320 and vice versa the total number of layers used in PWB 300 may be reduced significantly, as compared to the known prior art. Again, the inventive idea is to let return currents in the partial ground planes 330′, 330″ follow the signal currents through the PWB 300. The at least two partial reference ground planes 330′, 330″ may be interconnected by via-holes (not shown) around transition points which are arranged in proximity to a location where signal currents are configured to transit between the different layers of the PWB 300. The reference ground plane 330 can thus be said to be configured to jump or move between layers of the PWB 300 by making use of the various partial reference ground planes 330′, 330″ for forming the complete virtual reference ground plane 330, e.g., to maintain correct impedance for the conductors 310, 320.

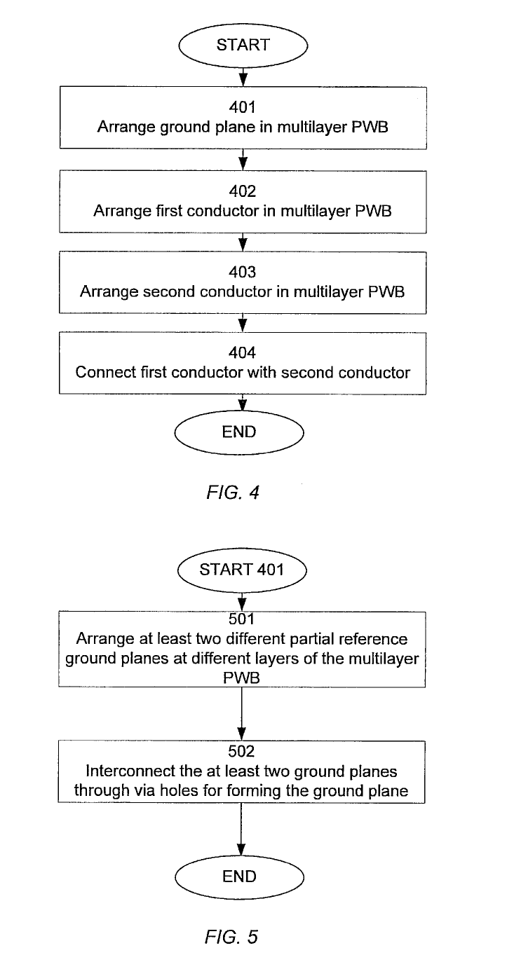

FIG. 4 is a flow chart which illustrates some of the major steps in producing or manufacturing a PWB 200, 300 according to an embodiment of the invention. The method illustrated in FIG. 4 is a method of manufacturing a multilayer PWB 200, 300, wherein the multilayer PWB 200, 300 has a first main surface 201, 301 and an opposing second main surface 202, 302, the PWB 200, 300 having a height h being defined by the distance from the first main surface 201, 301 to the opposing second main surface 202, 302, where said two surfaces and height together define the thickness of the PWB 200, 300. The method comprises arranging a reference ground plane 230, 330 in step 401, arranging a microstrip conductor 210, 310 such that the microstrip conductor 210, 310 is separated from the reference ground plane 230, 330 by a first dielectric layer in step 402, arranging a stripline conductor 220, 320 such that the stripline conductor 220, 320 is separated from the reference ground 230, 330 plane by a second dielectric layer in step 403, and connecting the microstrip conductor 210, 310 with the stripline conductor 220, 320, e.g., through a via-hole in step 404.

FIG. 5 illustrates some of the major sub-steps in arranging the reference ground plane 230, 330 in the PWB 200, 300. In step 501, at least two different partial reference ground planes 230′,230″, 330′,330″ are arranged at different layers of the multilayer PWB 200, 300 for thereby forming the reference ground plane 230, 330 in such way that the reference ground plane 230, 330 becomes moveable from a first partial reference ground plane 230′, 330′ to a second partial reference ground plane 230″, 330″ when a signal current transits from the microstrip 210, 310 conductor to the stripline conductor 220, 320, and vice versa. Furthermore, the method may include the step 502 of interconnecting the at least two partial reference ground planes at the different layers of the multilayer PWB by means of at least one via-hole. The step of interconnecting, i.e. step 502, may comprise interconnecting the at least two partial reference ground planes 230′,230″, 330′,330″ at the different layers of the multilayer PWB 200, 300 by means of the at least one via-hole such that a return current in the reference ground plane 230, 330 is moveable between the at least two partial reference ground planes 230′,230″, 330′,330″ for thereby following signal currents through the multilayer PWB 200, 300 when signal currents transit from the microstrip conductor to the stripline conductor, and vice versa.

In view of the above disclosure of various embodiments of the invention, it should be appreciated that some embodiments of the present invention provide an multilayer PWB 200, 300 with a reduced thickness as compared to prior art configuration of PWB's 100. It is an advantage with some embodiments of the invention that they allow for a PWB that can be made thinner. In turn, this may in turn lead to reduced manufacturing costs for producing the multilayer PWB. It is also an advantage of the various embodiments of this invention that they allow for the further miniaturization of mobile terminals, e.g. mobile phones, incorporating such multilayer PWB's.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

The foregoing has described the principles, embodiments and modes of operation of the present invention. However, the invention should be regarded as illustrative rather than restrictive, and not as being limited to the particular embodiments discussed above. The different features of the various embodiments of the invention can be combined in other combinations than those explicitly described. It should therefore be appreciated that variations may be made in those embodiments by those skilled in the art without departing from the scope of the present invention as defined by the following claims.

1. A multilayer printed wiring board, a multilayer PWB, with a first main surface and an opposing second main surface, the PWB having a height being defined by the distance from the first main surface to the opposing second main surface, said two surfaces and height together defining the thickness of the PWB, wherein the PWB comprises a reference ground plane, a microstrip conductor separated from the reference ground plane by a first dielectric layer, and a stripline conductor connected with the microstrip conductor and being separated from the reference ground plane by a second dielectric layer; wherein:
the reference ground plane is formed by at least two different partial reference ground planes positioned at different layers of the multilayer PWB, the reference ground plane being moveable from a first partial reference ground plane to a second partial reference ground plane when a signal current transits from the microstrip conductor to the stripline conductor, and vice versa.

2. The multilayer PWB as recited in claim 1, wherein the at least two partial reference ground planes at the different layers of the multilayer PWB are interconnected with each other by means of at least one via-hole.

3. The multilayer PWB as recited in claim 2, wherein the at least two partial reference ground planes are interconnected through said via-hole such that a return current in the reference ground plane is moveable between said at least two partial reference ground planes for following signal currents through the multilayer PWB when signal currents transit from the microstrip conductor to the stripline conductor, and vice versa.

4. An electronic device, comprising the PWB as recited in claim 1.

5. The electronic device according to claim 4, wherein the electronic device is a device from the group comprising: a portable radio communication equipment, a mobile radio terminal, a mobile telephone, a cellular telephone, a pager, a communicator, an electronic organizer, a smart phone, a camera device, a media player.

6. A method of manufacturing a multilayer printed wiring board, a multilayer PWB, said PWB having a first main surface and an opposing second main surface, the PWB having a height being defined by the distance from the first main surface to the opposing second main surface, said two surfaces and height together defining the thickness of the PWB, the method comprising:
arranging a reference ground plane,
arranging a microstrip conductor such that the microstrip conductor is separated from the reference ground plane by a first dielectric layer, and
arranging a stripline conductor such that the stripline conductor is separated from the reference ground plane by a second dielectric layer;
connecting the microstrip conductor with the stripline conductor;
the method further comprising:
arranging at least two different partial reference ground planes at different layers of the multilayer PWB for thereby forming the reference ground plane in such way that the reference ground plane becomes moveable from the first partial reference ground plane to the second partial reference ground plane when a signal current transits from the microstrip conductor to the stripline conductor, and vice versa.

7. The method as recited in claim 6, further comprising:
interconnecting the at least two partial reference ground planes at the different layers of the multilayer PWB by means of at least one via-hole.

8. The method as recited in claim 7, wherein the interconnecting comprises: interconnecting the at least two partial reference ground planes at the different layers of the multilayer PWB by means of the at least one via-hole such that a return current in the reference ground plane becomes moveable between the at least two partial reference ground planes for thereby following signal currents through the multilayer PWB when signal currents transit from the microstrip conductor to the stripline conductor, and vice versa.

9. An electronic device, comprising the PWB as recited in claim 2.

10. An electronic device, comprising the PWB as recited in claim 3.
